(19) United States
(12) Patent Application Publication
(10) Pub. No.: US 2010/0109085 A1
(43) Pub. Date: May 6, 2010

(54) MEMORY DEVICE DESIGN

(75) Inventors: Jinyoung Kim, Edina, MN (US); Yongchul Ahn, Eagan, MN (US); Muralikrishnan Balakrishnan, Bloomington, MN (US); Tangshiun Yeh, Arden Hill, MN (US); Antoine Khoueir, Apple Valley, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/408,112

(22) Filed: Mar. 20, 2009

Related U.S. Application Data
(60) Provisional application No. 61/111,353, filed on Nov. 5, 2008.

(51) Int. Cl. H01L 29/40; H01L 21/4763

(52) U.S. Cl. 257/364; 438/382; 257/E29.111; 257/E21.495

(57) ABSTRACT

Memory elements and methods for making memory elements. One method of making a memory element includes forming a first electrode, forming an electrically conductive current densifying element and a memory cell on the first electrode, the memory cell and the current densifying element adjacent to each other. A second electrode is formed over the current densifying element and the memory cell. The memory elements may be resistance random access memory elements.

### RELATED APPLICATIONS

This application claims priority to U.S. provisional patent application No. 61/111,353, filed on Nov. 5, 2008 and titled “New Integration Approach for ReRAM Device Fabrication”. The entire disclosure of application No. 61/111,353 is incorporated herein by reference.

### BACKGROUND

Modern semiconductor non-volatile memories, such as flash memory, have successfully achieved large capacity memories through improvements in photolithograph technology. However, conventional Flash memory scaling is nearing the technical and physical limits. To avoid this problem, alternate materials and/or structures have been proposed.

Recently, resistance random access memory (ReRAM or RRAM) has been extensively investigated not only because of its electrical performance but also because of its high scalable capability for memory array applications. ReRAM is based on materials such as metal oxides and organic compounds that show a resistive switching phenomenon. A ReRAM memory cell has a capacitor-like structure composed of insulating material or semiconducting material between two metal electrodes. Because of its simple structure and ease of manufacture, ReRAM devices are gaining acceptance for future memory.

### BRIEF SUMMARY

The present disclosure relates to memory elements and methods of making the memory elements.

In one particular embodiment, this disclosure provides a method for making a memory element that includes forming a first electrode, forming an electrically conductive current densifying element and a memory cell on the first electrode, with the memory cell and the current densifying element adjacent to each other. A second electrode is formed over the current densifying element and the memory cell.

In another particular embodiment, this disclosure provides a memory element that has a first electrode having a first area, a current densifying element having a second area less than the first area, a memory cell, and a second electrode having a third area greater than the second area. Each of the first electrode, the current densifying element, the memory cell and the second electrode in electrical connection. The memory cell may be a resistance random access memory cell.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a cross-sectional schematic diagram of an illustrative magnetic element;

FIGS. 2A and 2B are cross-sectional schematic diagrams of an illustrative resistive element, particularly, a programmable metallization memory element;

FIG. 3 is a schematic diagram of an illustrative memory array;

FIGS. 4A-4C are schematic step-wise diagrams of a method of making a memory element according to this disclosure;

FIGS. 5A-5C are schematic step-wise diagrams of a method of making a memory element according to this disclosure;

FIGS. 6A-6D are schematic step-wise diagrams of a method of making a memory element according to this disclosure; and

FIGS. 7A-7D are schematic step-wise diagrams of a method of making a memory element according to this disclosure.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

This disclosure is directed to memory elements and methods of making those elements. The memory elements include an electrically conductive current densifying element, which may be formed before or after forming the memory cell.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The present disclosure is directed to methods of making random access memory cells, such as resistance random access memory cells (ReRAM or RRAM). The methods and resulting memory cells provide improved electrical performance of ReRAM devices by minimizing process induced defects, such as chemical and mechanical damage during device fabrication. In addition to defect free fabrication, the methods can also reduce the cost of fabrication by reducing the number of masking steps.

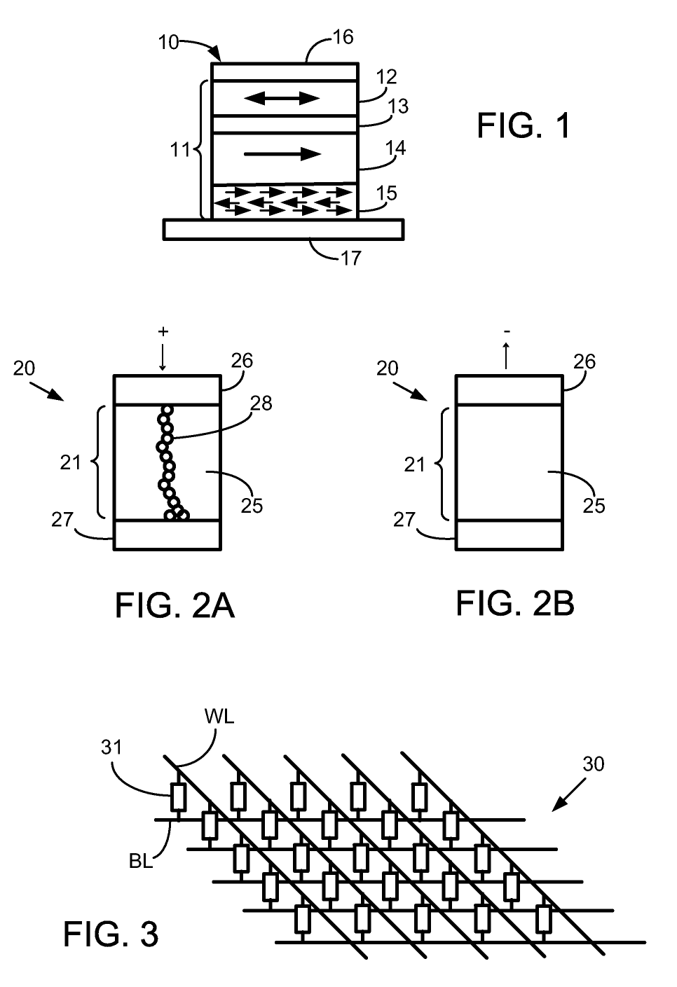

FIG. 1 is a cross-sectional schematic diagram of an illustrative magnetic element that can be formed by the methods of this disclosure. Element 10 of FIG. 1 may be referred to as a magnetic tunnel junction cell, variable resistive memory cell or variable resistance memory cell or the like. Magnetic memory element 10 includes magnetic cell or stack 11 composed of a ferromagnetic free layer 12 and a ferromagnetic reference (i.e., pinned) layer 14. Free layer 12 and pinned reference layer 14 are separated by a non-magnetic spacer layer 13. Proximate pinned reference layer 14 is an antiferromagnetic (AFM) pinning layer 15, which pins the magnetization orientation of pinned reference layer 14 by exchange bias with the antiferromagnetically ordered material of pinning layer 15. Examples of suitable pinning materials include PtMn, IrMn, and others. Note that other layers, such as seed or capping layers, are not depicted for clarity.

Ferromagnetic layers 12, 14 may be made of any useful ferromagnetic (FM) material such as, for example, Fe, Co or Ni and alloys thereof, such as NiFe and CoFe, and ternary alloys, such as CoFeB. Either or both of free layer 12 and pinned reference layer 14 may be either a single layer or a synthetic antiferromagnetic (SAF) coupled structure, i.e., two ferromagnetic sublayers separated by a metallic spacer, such as Ru or Cr, with the magnetization orientations of the sublayers in opposite directions to provide a net magnetization. Free layer 12 may be a synthetic ferromagnetic coupled structure, i.e., two ferromagnetic sublayers separated by a metallic spacer, such as Ru or Ta, with the magnetization orientations of the sublayers in parallel directions. Either or both layers 12, 14 are often about 0.1-10 nm thick, depending on the material and the desired resistance and switchability of free layer 12.

If magnetic element 10 is a magnetic tunnel junction cell, non-magnetic spacer layer 13 is an insulating barrier layer sufficiently thin to allow tunneling of charge carriers between pinned reference layer 14 and free layer 12. Examples of suitable electrically insulating material include oxides material (e.g., Al₂O₃, TiOₓ or MgOₓ). If magnetic element 10 is a spin-valve cell, non-magnetic spacer layer 13 is a conductive non-magnetic spacer layer. For either a magnetic tunnel junction cell or a spin-valve, non-magnetic spacer layer 13 could optionally be patterned with free layer 12 or with pinned reference layer 14, depending on process feasibility and device reliability.

The resistance across magnetic element 10 is determined by the relative orientation of the magnetization vectors or magnetization orientations of ferromagnetic layers 12, 14. The magnetization direction of ferromagnetic pinned reference layer 14 is pinned in a predetermined direction by pinning layer 15 while the magnetization direction of ferromagnetic free layer 12 is free to rotate under the influence of spin torque. In FIG. 1, the magnetization orientation of free layer 12 is illustrated as undefined. In some embodiments, magnetic tunnel junction element 10 is in the low resistance state where the magnetization orientation of free layer 12 is in the same direction or parallel to the magnetization orientation of pinned reference layer 14. In other embodiments, magnetic tunnel junction element 10 is in the high resistance state where the magnetization orientation of free layer 12 is in the opposite direction or anti-parallel to the magnetization orientation of pinned reference layer 14. In some embodiments, the low resistance state represents a “0” data bit and the high resistance state represents a “1” data bit, whereas in other embodiments, the low resistance state represents a “1” data bit and the high resistance state represents a “0” data bit.

Switching the resistance state and hence the data state of magnetic element 10 via spin-transfer occurs when a current, under the influence of a magnetic layer of magnetic element 10, becomes spin polarized and imparts a spin torque on free layer 12 of magnetic element 10. When a sufficient level of polarized current and therefore spin torque is applied to free layer 12, the magnetization orientation of free layer 12 can be changed among different directions and accordingly, magnetic element 10 can be switched between the parallel state, the anti-parallel state, and other states.

Electrically connected to cell 11 are a first or top electrode 16 and a second or bottom electrode 17. It is to be understood that the designations “top” and “bottom” are not to be limiting in their special relationship, but are merely used to facilitate understanding of the figures. In the following discussion, the term “top” is interchangeable with “first” and “bottom” is interchangeable with “second”. First electrode 16 is in electrical contact with ferromagnetic free layer 12 and second electrode 17 is in electrical contact with ferromagnetic pinned reference layer 14 via pinning layer 15. In this embodiment, second electrode 17 has a larger area (e.g., width and/or length) than cell 11. Electrodes 16, 17 electrically connect ferromagnetic layers 12, 14 to a control circuit providing read and write currents through layers 12, 14. Examples of materials for electrodes 16, 17 are conducting metal materials; suitable materials include TiN, TaN and Cu.

The illustrative magnetic element 10 is used to construct a memory device where a data bit is stored in the spin torque memory cell by changing the relative magnetization state of free layer 12 with respect to pinned reference layer 14. The stored data bit can be read out by measuring the resistance of element 10 which changes with the magnetization direction of free layer 12 relative to pinned reference layer 14.

FIGS. 2A and 2B are cross-sectional schematic diagrams of an illustrative resistive random access memory element, in particular, a programmable metallization memory element 20, which can be made by the methods of this disclosure; in FIG. 2A, memory element 20 is in the low resistance state and in FIG. 2B, memory element 20 is in the high resistance state. Programmable metallization cell (PMC) memory is based on the physical re-location of superionic regions within an ion conductor solid electrolyte material.

Memory element 20 includes a memory cell 21 with a first metal electrode 26, a second metal electrode 27, and an ion conductor solid electrolyte material 25 therebetween.

In FIG. 2A, application of an electric current (+) to first electrode 26 allows cations from electrode 26 to migrate toward second electrode 27, forming conducting filaments 28 or superionic clusters within ion conductor solid electrolyte material 25. The presence of conducting filaments 28 or superionic clusters within ion conductor solid electrolyte material 25 reduces the electrical resistance between first electrode 26 and second electrode 27 and gives rise to the low resistance state of programmable metallization memory element 20.

Reading memory element 20 simply requires a small voltage applied across the cell. If conducting filaments 28 are present in that cell, the resistance will be low and the element will be in the low data state. If there are no conducting filaments 28 present, the resistance is higher, which can be read as the opposite state, as illustrated in FIG. 2B. In some embodiments, the low resistance state represents a “0” data bit and the high resistance state represents a “1” data bit, whereas in other embodiments, the low resistance state represents a “1” data bit and the high resistance state represents a “0” data bit.

Application of an electric current of opposite polarity (−) to memory element 20 ionizes conducting filaments 28 and moves the ions back to first electrode 26 and gives rise to the high resistance state of memory element 20. The low resistance state and the high resistance state are switchable with an applied electric field and are used to store the memory bit “1” or “0”.

Ion conductor solid electrolyte material 25 can be formed of any useful material that provides for the formation of conducting filaments 28 or superionic clusters within ion conductor solid electrolyte material 25 that extend between metal electrode 26 and metal electrode 27 upon application of an electric current. In some embodiments, ion conductor solid electrolyte material 25 is a chalcogenide-type material such as, for example, GeS₂, GeSe₂, CuS₂, and the like. In other embodiments, ion conductor solid electrolyte material 25 is an oxide-type material such as, for example, NiO, WO₃, SiO₂, and the like.

First metal electrode 26 and second metal electrode 27 can be formed of any electrically conductive material such as metallic material. In many embodiments, one or both of first metal electrode 26 and second metal electrode 27 are formed of electrically conductive yet electrochemically inert metals such as, for example, Pt, Au, and the like. In some embodiments, first metal electrode 26 and/or second metal electrode 27 have two or more metal layers, where the metal layer closest to ion conductor solid electrolyte material 25 is electrochemically inert while additional layers can be electrochemically active.

Memory element 20 is a programmable metallization cell (PMC), a resistive memory element where the data state of the element depends on the resistance across the element. For element 20, the resistance across cell 21 decreases with the presence of conducting filaments 28. Other resistive memory elements that can be made by the methods of this disclosure include those that function based on carrier movement on the interface (e.g., phase change memory cells (PCM or PCRAM) and those that function based on ion transport in solid electrolyte (e.g., perovskite metal oxide cells (e.g. perovskite manganites, Pr₁₋ₓCaₓMnO₃, or perovskite titanates) (PCMO)).

FIG. 3 is a schematic diagram of an illustrative memory array 30. Memory array 30 includes a plurality of word lines WL and a plurality of bit lines BL forming a cross-point array. At each cross-point a memory element 31, such as memory element 10 of FIG. 1 or memory element 20 of FIGS. 2A and 2B, is electrically coupled to word line WL and bit line BL. Memory element 31 includes a memory cell, such as for example, memory cell 11 of FIG. 1 or memory cell 21 of FIGS. 2A and 2B.

The above-described memory elements and other memory elements of this disclosure may be made by various methods. Some of the methods of this disclosure include forming a first electrode, forming an electrically conductive current densifying element and a memory cell in electrical contact with the first electrode, and patterning a second electrode over the current densifying element and the memory cell. The current densifying element may be formed before or after forming the memory cell. Other methods of this disclosure include forming a first electrode, providing a hole in an electrically insulating layer, the hole extending to the first electrode; forming an electrically conductive current densifying element in the hole and forming a memory cell in the hole, with the memory cell and the current densifying element adjacent to each other. After filling the hole with the current densifying element and the memory cell, patterning a second electrode over the filled hole. The electrically conductive current densifying element may be formed in the hole before or after forming the memory cell in the hole.

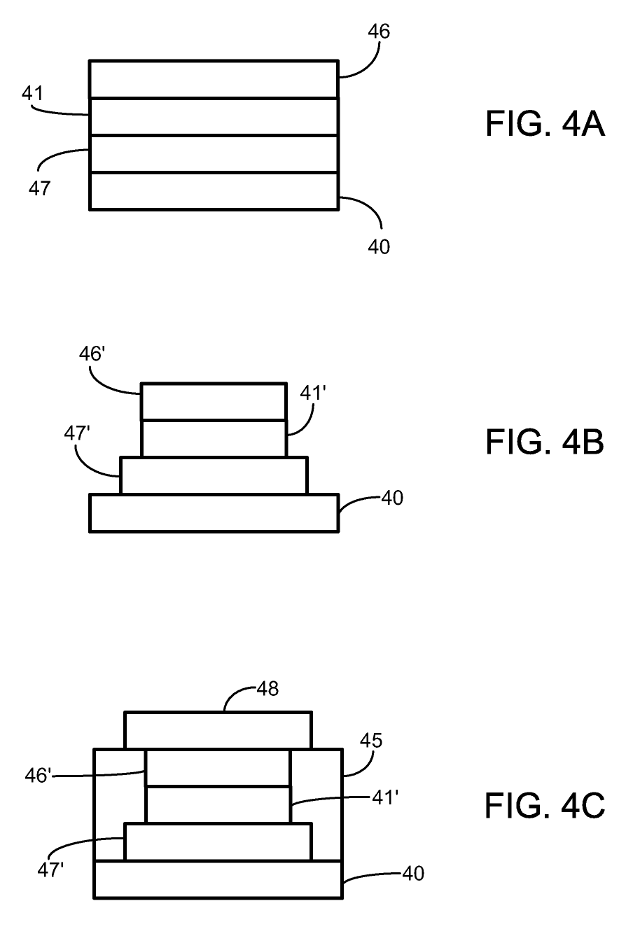

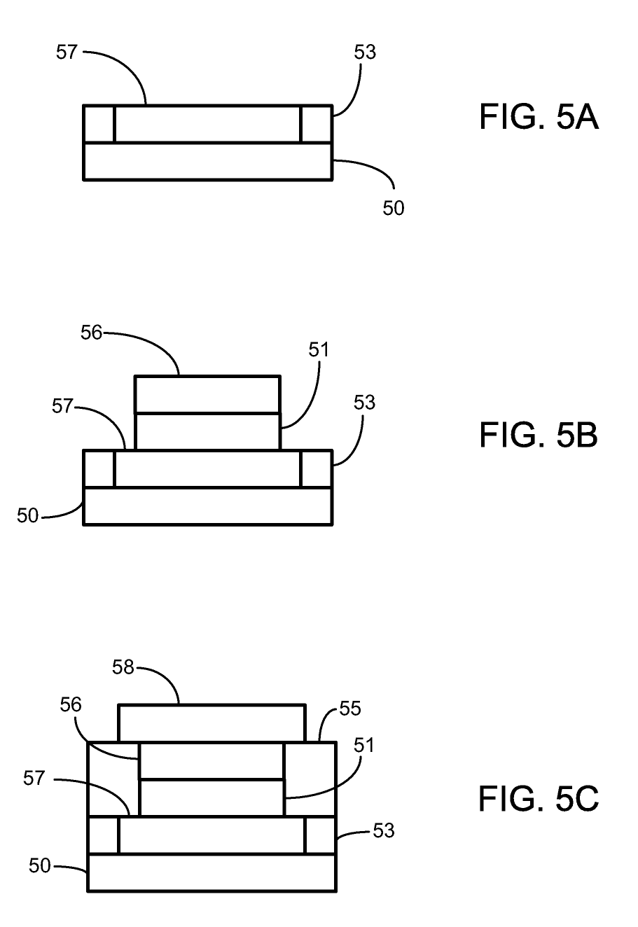

FIGS. 4A-4C and FIGS. 5A-5D illustrate two specific methods for producing a memory element having a memory cell with a bottom lead or electrode and a top lead or electrode. The method of FIGS. 4A-4C can be referred to as a “bottom electrode last” method for making a memory element, where the bottom electrode is shaped or patterned after the corresponding memory cell is formed. The method of FIGS. 5A-5C can be referred to as a “bottom electrode first” method for making a memory element, where the bottom electrode is shaped or patterned before the corresponding memory cell is formed.

In the “bottom electrode last” method, the bottom electrode is fabricated on the substrate (e.g., silicon wafer) followed by deposition of the memory cell and the top electrode. Patterning and etching of the top electrode and the memory stack are done to form the eventual final top electrode and the memory stack; during this step, the bottom electrode functions as a hard mask, inhibiting of etching past the memory cell. Subsequently, patterning and etching are done to form the eventual bottom electrode. This integration is called “bottom electrode last” because the bottom element is defined at very last step of patterning, after formation of the final memory cell and the top electrode.

Referring to FIG. 4A, a substrate 40 has formed (e.g., deposited) thereon a bottom lead electrode material 47. A memory cell layer 41 is formed on electrode material 47, over which a top lead electrode material 46 is deposited.

Substrate 40 may be, for example, a dielectric or an oxide material such as SiO₂, Al₂O₃, FSG (fluorinated silicate glass, a silica based low-k dielectric), CDO (carbon doped oxide), doped SiO₂, SiN, or MgOₓ. In some embodiments, substrate 40 may be multiple layers, such as multiple metallization layers fabricated on an “n” silicon doped substrate. Electrode materials 46, 47 are electrically conductive materials and are usually a metal material. Examples of suitable materials for electrode materials 46, 47 include TiN, TaN, Cu, and W. Electrode materials 46, 47 may have the same or different materials, and may have the same or different thicknesses. In some embodiments, bottom electrode material 47 has a thickness of about 1000 Å and top electrode material 46 has a thickness of about 2000 Å. For embodiments where the eventual memory cell is a magnetic tunnel junction element, such as element 10 of FIG. 1, memory cell layer 41 includes two ferromagnetic layers and a spacer layer therebetween. In some embodiments, the thickness of memory cell layer 41 is about 600 Å.

In FIG. 4B, top electrode material 46 and memory cell material 41 are patterned and etched to form a top electrode 46′ and memory cell 41′, respectively. After forming top electrode 46′ and memory cell 41′ with their final configuration, bottom electrode material 47 is patterned and etched to form bottom electrode 47′.

In FIG. 4C, an interlayer dielectric (ILD) layer 45 is deposited around memory cell 41′ and electrodes 46′, 47′. If necessary, ILD layer 45 may be polished (e.g., planarized, e.g., by chemical-mechanical polishing (CMP)). An additional metal layer 48 is patterned and etched to make an electrical connection to memory cell 41′.

Suitable materials for ILD layer 45 include dielectric or oxide materials such as SiO₂, Al₂O₃, FSG, CDO, doped SiO₂, and SiN. ILD layer 45 may be the same material or different than substrate 40.

In the “bottom electrode first” method, the bottom electrode is fabricated and patterned on the substrate followed by deposition of the memory cell and the top electrode. This integration is called “bottom electrode first” because the bottom element is defined prior to formation of the final memory cell and the top electrode. “Bottom electrode first” methods have been used to obtain high magnetic and electrical performance by minimizing substrate stress effect on the adjacent memory cell. The various materials and their properties (e.g., layer thicknesses) for a “bottom electrode first” process are generally the same as or similar to those of a “bottom electrode last” process, unless indicated otherwise.

Referring to FIG. 5A, a substrate 50 has formed (e.g., deposited) thereon a bottom lead electrode 57. Bottom electrode 57 may be formed in the eventual final configuration, or may be patterned and etched. An interlayer dielectric (ILD) layer 53 is deposited around electrode 57. If necessary, ILD layer 53 may be polished (e.g., planarized, e.g., by chemical-mechanical polishing (CMP)) to be level with bottom electrode 57.

Memory cell 51 and a top electrode 56 are formed (e.g., deposited) in FIG. 5B over bottom electrode 57. Memory cell 51 and a top electrode 56 may be formed in the eventual final configuration, or may be patterned and etched.

In FIG. 5C, a second interlayer dielectric (ILD) layer 55 is deposited over bottom electrode 57 and the first ILD layer 53. Second ILD layer 55 surrounds memory cell 51 and a top electrode 56, and may be polished (e.g., planarized, e.g., by CMP), if necessary, to be level with top electrode 56. An additional metal layer 48 is patterned and etched to make an electrical connection to memory cell 51.

The two methods described above, “bottom electrode last” and “bottom electrode first” are particularly suitable integration techniques for spin-toque memory device fabrication (e.g., ST RAM devices) due to their simplicity and compatibility with current CMOS technology. Memory element 10 of FIG. 1 is a spin-torque memory element. Recently, resistance random access memory (ReRAM or RRAM) has been extensively investigated not only because of its electrical performance but also high scalable capability for memory array applications. Memory element 20 of FIG. 2 is one embodiment of a resistive memory element. However, the requirement for ReRAM operation requires a different type of electrodes, as compared to ST RAM devices due to the characteristics of the ReRAM devices, characteristics such as the conduction mechanism of the memory cell.

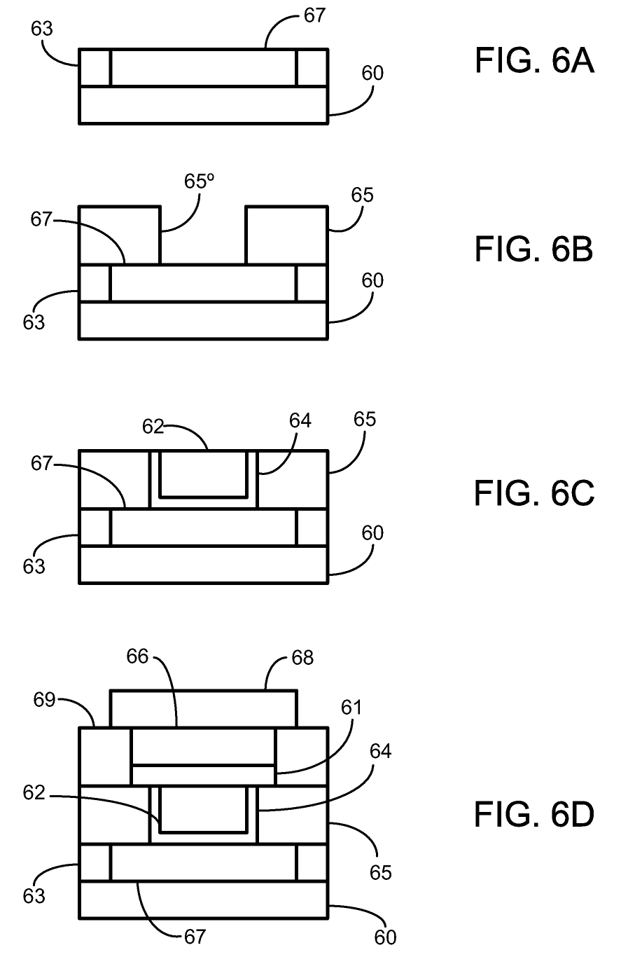

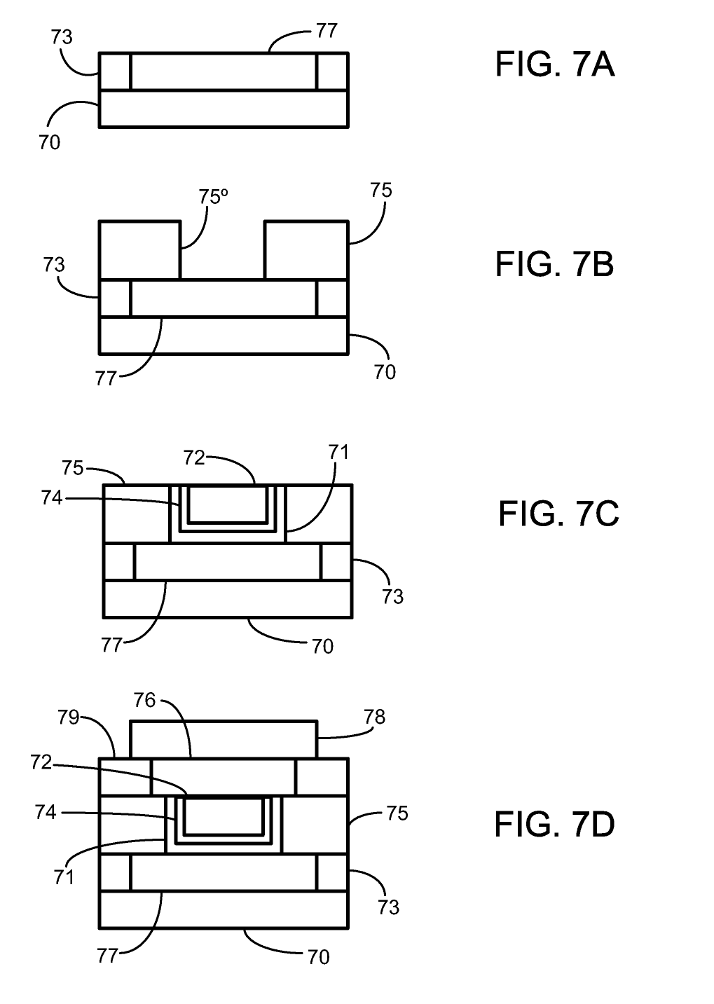

FIGS. 6A-6D and FIGS. 7A-7D illustrate two methods for producing a memory element having a memory cell with a bottom lead or electrode and a top lead or electrode. These methods are especially suited for ReRAM elements, as these methods provide structures that, in use, readily densify current through the element from the electrode, which better meets the needs of ReRAM electrical performance. The various materials and their properties (e.g., layer thicknesses) for the methods of FIGS. 6A-6D and FIGS. 7A-7D are generally the same as or similar to those of the “bottom electrode last” process of FIGS. 4A-4C and the “bottom electrode first” process of FIGS. 5A-5C, unless indicated otherwise.

In each of these methods, a current densifying element is formed between the bottom contact or electrode and the memory cell. This element resembles a plug, with a size or diameter of at least 50 nm, in some embodiments at least 75 nm and in other embodiments at least 100 nm. In some embodiments, the current densifying element has a size no greater than about 200 nm, sometimes no greater than about 150 nm. The physical shape and size (e.g., diameter, area, etc.) of the current densifying element is less than the adjacent bottom electrode or top electrode. Due to its physical shape, the current densifying element increases the density of the current passing between the electrodes and enhances any electric field around the memory cell.

FIGS. 6A-6D illustrate a first method for producing a memory element having a memory cell with a current densifying element proximate the bottom lead or electrode, so that the memory cell is positioned between the current densifying element and the top electrode.

Referring to FIG. 6A, a substrate 60 has formed (e.g., deposited) thereon a bottom lead electrode 67. Bottom electrode 67 may be formed in the eventual final configuration, or may be patterned and etched. An interlayer dielectric (ILD) layer 63 is deposited around electrode 67. If necessary, ILD layer 63 may be polished (e.g., planarized, e.g., by chemical-mechanical polishing (CMP)) to be level with bottom electrode 67.

In FIG. 6B, a continuous second interlayer dielectric (ILD) layer 65 is deposited over bottom electrode 67; in most embodiments, second ILD layer 65 is the same material as ILD layer 63. ILD layer 65 is etched (e.g., via a damascene process) to provide a hole, void or well 65^{o} having a size less than that of bottom electrode 67 and preferably centered over bottom electrode 67. Hole 65^{o} extends through the thickness of ILD layer 65 to electrode 67 and has a diameter, of at least about 25 nm and usually less than 200 nm. In some embodiments, this hole 65^{o} has a diameter of at least about 50 nm. In some embodiments, the diameter is about 100 to 150 nm.

In FIG. 6C, hole 65^{o} is filled with an electrically conductive plug 62, which forms the current densifying element. Examples of materials suitable for plug 62 are electrically conducting materials, including metals such as W and Al. In some embodiments, prior to filling hole 65^{o} with plug 62, hole 65^{o} is lined with a barrier layer 64, which may be applied on either or both bottom electrode 67 and ILD layer 65. Examples of materials suitable for barrier 64 are electrically conducting materials, including metals such as TiN for W, and TaN for Cu. Barrier 64 may be the same or different material than bottom electrode 67. Plug 62, ILD layer 65 and optional barrier 64 may be polished (e.g., planarized, e.g., by CMP), if necessary, to be level.

Memory cell 61 and a top electrode 66 are formed (e.g., deposited) in FIG. 6D over the current densifying element composed of optional barrier layer 64 and plug 62, with memory cell 61 directly on plug 62. Memory cell 61 may be a magnetic memory cell (e.g., a spin torque memory cell), such as memory cell 11 of FIG. 1 or a resistive memory cell (e.g., programmable metallization cell (PMC), phase change memory cells (PCM), or perovskite metal oxide cells (PCMO)), such as memory cell 21 of FIGS. 2A and 2B. Memory cell 61 and top electrode 66 may be formed in the eventual final configuration, or may be patterned and etched. A third interlayer dielectric (ILD) layer 69 is deposited around memory cell 61 and electrode 66; in most embodiments, ILD layer 69 is the same material as ILD layer 63 and second ILD layer 65. Third ILD layer 69 surrounds memory cell 61 and a top electrode 66, and may be polished (e.g., planarized, e.g., by CMP), if necessary, to be level with top electrode 66. An additional metal layer 68 may be applied and patterned and etched as desired.

In use, electrical current passes through the element, having a path from bottom electrode 67, through optional barrier layer 64, through plug 62, through memory cell 61, to electrode 66 and optional metal layer 68. In some embodiments, current may pass the other direction, from top electrode 66 through memory cell 61 to bottom electrode 67. Plug 62, having a smaller area (e.g., at least 50 nm, in some embodiments at least 75 nm and in other embodiments at least 100 nm, with a size no greater than about 200 nm, sometimes no greater than about 150 nm) than bottom electrode 67 and/or top electrode 66 (which are often about 200 nm to about 250 nm), concentrates the current from electrode 66 or electrode 67, increasing the current density into memory cell 61.

The resulting memory element made by the method of FIGS. 6A-6D has a current densifying element proximate the bottom lead or electrode with the memory cell positioned between the current densifying element and the top electrode. Such a structure is particularly suited for ReRAM devices, as the current densifying element increases the current density through the memory cell. ReRAM elements made by the method of FIGS. 6A-6D have better electrical performance than ReRAM elements made by either the “bottom electrode last” process of FIGS. 4A-4C or the “bottom electrode first” process of FIGS. 5A-5C, described above. In the method of FIGS. 6A-6D, the dimensions of the memory cell are affected by the interface area between the top electrode (i.e., top electrode 66), and the memory cell (i.e., memory cell 61). This interface area provides a well controlled field distribution.

FIGS. 7A-7D illustrate a first method for producing a memory element having a memory cell with a current densifying element proximate the top lead or electrode, so that the memory cell is positioned between the bottom electrode and the current densifying element. The method of FIGS. 7A-7D is similar to that of FIGS. 6A-6D, described above, except that instead of filling hole 65^{o} with plug 62 and then forming memory cell 61, the memory cell is directly deposited into the hole and the plug is formed afterward.

Referring to FIG. 7A, a substrate 70 has formed (e.g., deposited) thereon a bottom lead electrode 77. Bottom electrode 77 may be formed in the eventual final configuration, or may be patterned and etched. An interlayer dielectric (ILD) layer 73 is deposited around electrode 77. If necessary, ILD layer 73 may be polished (e.g., planarized, e.g., by CMP) to be level with bottom electrode 77.

In FIG. 7B, a continuous second interlayer dielectric (ILD) layer 75 is deposited over bottom electrode 77; in most embodiments, second ILD layer 75 is the same material as ILD layer 73. ILD layer 75 is etched (e.g., via a damascene process) to provide a hole 75^{o} having a size less than that of bottom electrode 77 and preferably centered over bottom electrode 77. hole 75^{o} has a diameter, of at least about 25 nm and usually less than 200 nm. In some embodiments, hole 75^{o} has a diameter of at least about 50 nm. In some embodiments, the diameter is about 100 to 150 nm.

In FIG. 7C, a memory cell 71 is formed within hole 75^{o} against bottom electrode 77. Memory cell 71 may be a magnetic memory cell (e.g., a spin torque memory cell), such as memory cell 11 of FIG. 1 or a resistive memory cell (e.g., programmable metallization cell (PMC), phase change memory cells (PCM), or perovskite metal oxide cells (PCMO)), such as memory cell 21 of FIGS. 2A and 2B. In this illustrated embodiment, a portion of memory cell 71 extends up along the side walls of ILD layer 75. After forming memory cell 71 in hole 75^{o}, a plug 72 is formed over cell 71 filling hole 75^{o} and forming the current densifying element. Examples of materials suitable for plug 72 are electrically conducting materials, including metals such as W and Al. In some embodiments, prior to forming plug 72 over memory cell 71 in hole 75^{o}, an optional barrier layer 74 may be applied on memory cell 71. Examples of materials suitable for barrier 74 are electrically conducting materials, including metals such as TiN for W, and TaN for Cu. Plug 72, ILD layer 75 and optional barrier layer 74 may be polished (e.g., planarized, e.g., by CMP), if necessary, to be level.

A top electrode 76 is formed (e.g., deposited) in FIG. 7D over the current densifying element formed by plug 72. Top electrode 76 may be formed in the eventual final configuration, or may be patterned and etched. A third interlayer dielectric (ILD) layer 79 is deposited around electrode 76 and may be polished (e.g., planarized, e.g., by CMP), if necessary, to be level with top electrode 76; in most embodiments, ILD layer 79 is the same material as ILD layer 73 and second ILD layer 75. An additional metal layer 78 may be applied over electrode 76.

In use, electrical current passes through the element, having a path from bottom electrode 77, through memory cell 71, through optional barrier layer 74, through plug 72, to electrode 76 and optional metal layer 78. In some embodiments, current may pass the other direction, from top electrode 76 through memory cell 71 to bottom electrode 77. Plug 72, having a smaller area (e.g., at least 50 nm, in some embodiments at least 75 nm and in other embodiments at least 100 nm, with a size no greater than about 200 nm, sometimes no greater than about 150 nm) than bottom electrode 77 and/or top electrode 76 (which are often about 200 nm to about 250 nm), concentrates the current from electrode 76 or electrode 77, increasing the current density into memory cell 71.

The resulting memory element made by the method of FIGS. 7A-7D has a current densifying element proximate the top lead or electrode with the memory cell positioned between the current densifying element and the bottom electrode. Such a structure is particularly suited for ReRAM devices, as the current densifying element increases the current density through the memory cell. ReRAM elements made by the method of FIGS. 7A-7D have better electrical performance than ReRAM elements made by either the “bottom electrode last” process of FIGS. 4A-4C or the “bottom electrode first” process of FIGS. 5A-5C, described above. In the method of FIGS. 7A-7D, the dimensions of the memory cell are affected by the interface area between the bottom electrode (i.e., bottom electrode 77), and the memory cell (i.e., memory cell 71). This interface area provides a well controlled field distribution.

In some embodiments, the process of FIGS. 7A-7D, forming memory cell 71 prior to forming plug 72, is preferred over the process of FIGS. 6A-6D. Depending on the exact masking and etching steps done, the method of FIGS. 7A-7D uses at least one less masking step than the method of FIGS. 6A-6D. Further, the method of FIGS. 7A-7D inhibits process induced defects formed during the memory cell fabrication process, because the memory cell is not exposed to any chemical and/or CMP process.

Various methods for making memory elements have been described above. In some methods, a current densifying element is formed between a contact or electrode and the memory cell. Due to its physical shape, the current densifying element increases the density of the current passing between the electrodes and enhances any electric field around the memory cell. Such a current densifying element is particularly useful for restrictive random access memory (ReRAM or RRAM) elements.

Thus, embodiments of the MEMORY DEVICE DESIGN are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A method of making a memory element comprising:
forming a first electrode;
forming an electrically conductive current densifying element and a memory cell in electrical contact with the first electrode, the memory cell and the current densifying element adjacent to each other; and
patterning a second electrode over the current densifying element and the memory cell.

2. The method of claim 1 wherein forming the current densifying element is done before forming the memory cell.

3. The method of claim 2 wherein forming the current densifying element and forming the memory cell comprises forming the electrically conductive current densifying element and the memory cell in a hole in an electrically insulating layer over the first electrode.

4. The method of claim 3 wherein forming the electrically conductive current densifying element and the memory cell in a hole in an electrically insulating layer comprises applying a barrier layer in the hole prior to forming the electrically conductive current densifying element and the memory cell.

5. The method of claim 3, after forming the current densifying element and forming the memory cell, polishing the memory cell.

6. The method of claim 5 wherein polishing the memory cell comprises chemical-mechanical polishing (CMP) of the memory cell.

7. The method of claim 1 wherein forming the current densifying element is done after forming the memory cell.

8. The method of claim 7 wherein forming the current densifying element and forming the memory cell comprises forming the electrically conductive current densifying element and the memory cell in a hole in an electrically insulating layer over the first electrode.

9. The method of claim 8 wherein forming the electrically conductive current densifying element and the memory cell in a hole in an electrically insulating layer comprises applying a barrier layer in the hole prior to forming the electrically conductive current densifying element and the memory cell.

10. The method of claim 8, after forming the current densifying element and forming the memory cell, polishing the current densifying element.

11. The method of claim 10 wherein polishing the current densifying element comprises chemical-mechanical polishing (CMP) of the current densifying element.

12. The method of claim 1 wherein forming a memory cell comprises forming a resistance random access memory cell.

13. A method of making a memory element comprising:
forming a first electrode;
providing a hole in an electrically insulating layer, the hole extending to the first electrode;
forming an electrically conductive current densifying element in the hole;
forming a memory cell in the hole, the memory cell and the current densifying element adjacent to each other and filling the hole; and
patterning a second electrode over the filled hole.

14. The method of claim 13 wherein forming an electrically conductive current densifying element in the hole is done prior to forming a memory cell in the hole.

15. The method of claim 13 wherein forming an electrically conductive current densifying element in the hole is done after forming a memory cell in the hole.

16. A memory element comprising:
a first electrode having a first area;
a current densifying element having a second area less than the first area;
a memory cell; and
a second electrode having a third area greater than the second area,
with each of the first electrode, the current densifying element, the memory cell and the second electrode in electrical connection.

17. The memory element of claim 16 wherein the memory cell is a resistance random access memory cell.

18. The memory element of claim 16 wherein the current densifying element comprises Al or W.

19. The memory element of claim 16 wherein the current densifying element has a diameter of 50 nm to 200 nm.

20. The memory element of claim 19 wherein the current densifying element has a diameter of 100 nm to 150 nm.
